(19) United States
(12) Patent Application Publication
(10) Pub. No.: US 2026/0247648 A1
(43) Pub. Date: Aug. 20, 2026

(54) III-V COMPOUND SEMICONDUCTOR LAYER STACKS ON STRAIN-RELIEVED SEMICONDUCTOR SUBSTRATES

(71) Applicant: GlobalFoundries U.S. Inc., Malta, NY (US)

(72) Inventors: Jacob DeAngelis, South Burlington, VT (US); Mark Levy, Williston, VT (US); Fuad Al-Amoody, Colchester, VT (US)

(21) Appl. No.: 19/056,947

(22) Filed: Feb. 19, 2025

(51) Int. Cl. H10D 30/47; H10D 62/82; H10D 62/834; H10D 62/85; H10P 30/20; H10P 95/90

(52) U.S. Cl. CPC H10D 30/471; H10D 62/82; H10D 62/834; H10D 62/8503; H10P 30/206; H10P 30/208; H10P 95/904

(57) ABSTRACT

Structures including a layer stack of compound semiconductor materials arranged on a substrate and methods of forming such structures. The structure comprises a semiconductor substrate including a top surface, a first layer, and a second layer. The first layer is arranged between the second layer and the top surface. The semiconductor substrate comprises a semiconductor material, the semiconductor material of the first layer is single crystal, and the semiconductor material of the second layer is non-single-crystal. The structure further comprises a layer stack on the top surface of the semiconductor substrate.

### STATEMENT REGARDING FEDERALLY SPONSORED RESEARCH OR DEVELOPMENT

This invention was made with government support under HQ0727790700 awarded by the Defense Microelectronics Activity. The government has certain rights in the invention.

### BACKGROUND

The disclosure relates to semiconductor device fabrication and integrated circuits and, more specifically, to structures including a layer stack of compound semiconductor materials arranged on a substrate and methods of forming such structures.

Compound semiconductor materials are characterized by advantageous material properties, such as a carrier mobility that is higher than the carrier mobility of silicon and a wider band gap than silicon, that can be exploited to fabricate device structures. Compound semiconductor materials may include, for example, Group III elements (e.g., aluminum, gallium, and/or indium) and Group V elements (e.g., nitrogen, phosphorus, arsenic, and/or antimony) combined with the Group III elements.

High-electron-mobility transistors based on compound semiconductor materials can be deployed in certain integrated circuit applications, such as high-voltage power electronics. A high-electron-mobility transistor may include a heterojunction between crystalline compound semiconductor materials having different band gaps, such as a heterojunction between binary gallium nitride and trinary aluminum-gallium nitride. During operation, a high concentration of high-mobility electrons accumulates near the heterojunction to supply a two-dimensional electron gas.

A layer stack of compound semiconductors may be formed on a silicon substrate and used to fabricate a high-electron-mobility transistor. The layer stack includes a thick buffer layer between the heterojunction and the silicon substrate. The buffer layer is tailored to accommodate the lattice mismatch between the lattice parameters of the silicon substrate and the lattice parameters of the compound semiconductors in the layer stack. However, the failure of the buffer layer to adequately accommodate the lattice mismatch at a reasonable thickness may result in significant tensile strain in the layer stack. The tensile strain can significantly affect the electronic and mechanical properties of the compound semiconductor materials in the layer stack, potentially impacting the performance of the high-electron-mobility transistor.

Improved structures including a layer stack of compound semiconductor materials arranged on a substrate and methods of forming such structures are needed.

### SUMMARY

In an embodiment of the invention, a structure comprises a semiconductor substrate including a top surface, a first layer, and a second layer. The first layer is arranged between the second layer and the top surface. The semiconductor substrate comprises a semiconductor material, the semiconductor material of the first layer is single crystal, and the semiconductor material of the second layer is non-single-crystal. The structure further comprises a layer stack on the top surface of the semiconductor substrate.

In an embodiment of the invention, a method comprises forming a first layer and a second layer of a semiconductor substrate. The first layer is arranged between the second layer and a top surface of the semiconductor substrate, the semiconductor substrate comprises a semiconductor material, the semiconductor material of the first layer is single crystal, and the semiconductor material of the second layer is non-single-crystal. The method further comprises forming a layer stack on the top surface of the semiconductor substrate.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a structure at an initial fabrication stage of a processing method in accordance with embodiments of the invention.

FIG. 2 is a cross-sectional view of the structure at a fabrication stage of the processing method subsequent to FIG. 1.

FIG. 3 is a cross-sectional view of the structure at a fabrication stage of the processing method subsequent to FIG. 2.

FIG. 4 is a cross-sectional view of the structure at a fabrication stage of the processing method subsequent to FIG. 3.

FIG. 5 is a cross-sectional view of the structure at a fabrication stage of the processing method subsequent to FIG. 4.

FIG. 6 is a cross-sectional view of the structure at a fabrication stage of the processing method subsequent to FIG. 5.

FIG. 7 is a cross-sectional view of the structure at a fabrication stage of the processing method subsequent to FIG. 6.

FIG. 8 is a cross-sectional view of a structure in accordance with alternative embodiments of the invention.

FIG. 9 is a cross-sectional view of a structure in accordance with alternative embodiments of the invention.

### DETAILED DESCRIPTION

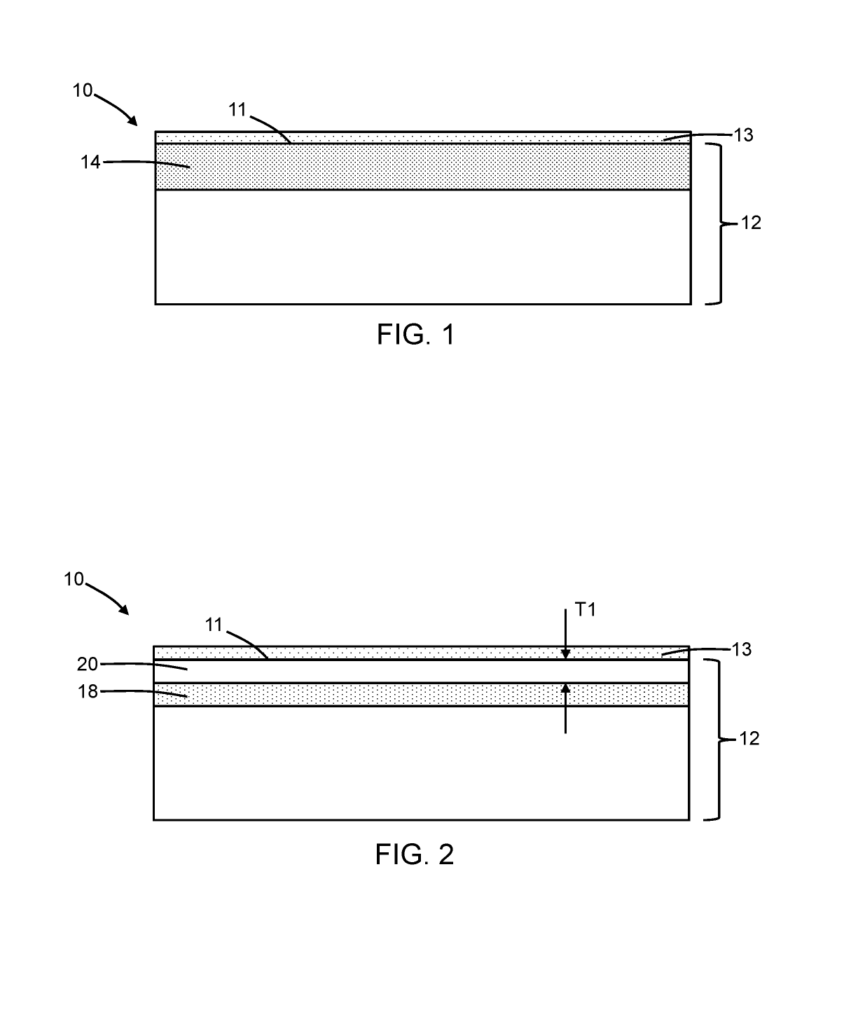

With reference to FIG. 1 and in accordance with embodiments of the invention, a structure 10 includes a semiconductor substrate 12 that is comprised of a single-crystal semiconductor material, such as single-crystal silicon, that is crystalline. In an embodiment, the single-crystal semiconductor material of the semiconductor substrate 12 may be oriented with a <111> surface normal. A dielectric layer 13 comprised of, for example, an oxide of silicon, such as silicon dioxide, may be applied to a top surface 11 of the semiconductor substrate 12.

An implanted layer 14 comprised of a semiconductor material is formed in the semiconductor substrate 12. In an embodiment, the semiconductor material within the implanted layer 14 may be comprised of damaged semiconductor material. In an embodiment, the semiconductor material within the implanted layer 14 may be comprised of amorphous semiconductor material.

The implanted layer 14 may be formed by an ion implantation process that introduces energetic ions, as indicated diagrammatically by the single-headed arrows, with ion trajectories that travel in paths within the semiconductor material of the semiconductor substrate 12. The energetic ions lose energy along their paths via stochastic scattering events with atomic nuclei and electrons in the traversed semiconductor material. Energy lost in nuclear collisions displaces target atoms of the semiconductor substrate 12 from their original lattice sites, which damages the crystal lattice structure of the semiconductor substrate 12 and generates point defects. The crystal lattice structure of the semiconductor substrate 12 is damaged or amorphized within the implanted layer 14 in comparison with an undamaged region of the single-crystal semiconductor material of the semiconductor substrate 12 positioned below a lower boundary of the implanted layer 14. The implanted layer 14 of the semiconductor substrate 12 may be changed from crystalline semiconductor material (e.g., single-crystal silicon) to damaged or amorphous semiconductor material (e.g., damaged or amorphous silicon) as a consequence of the use of a high dose of the implanted species. A thickness of the implanted layer 14 adjacent to the top surface 11 may be more lightly damaged that underlying heavily-damaged regions of the implanted layer 14 due to the variations in the amount of damage to the crystal lattice structure with depth. The dielectric layer 13 protects the top surface 11 during implantation.

The ions may be generated from a suitable source gas and implanted into the semiconductor substrate 12 with one or more implantation conditions using an ion implantation tool. The implantation conditions, such as ion species, dose, and energy, for the ion implantation process may be selected to tune the characteristics of the implanted layer 14. In an embodiment, the ions may be generated from a noble gas, such as Ar. In an embodiment, the dose of argon ions chosen for the implantation may be greater than to 4x10¹⁴ ions/cm². In an embodiment, the dose of argon ions chosen for the implantation may be within a range of 1x10¹⁴ ions/cm² to 5x10¹⁵ ions/cm². In an embodiment, the kinetic energy of the argon ions chosen for the implantation may be in a range of about 30 keV to about 1000 keV. The kinetic energy and dose for other implanted noble gas species may be similar.

With reference to FIG. 2 in which like reference numerals refer to like features in FIG. 1 and at a subsequent fabrication stage of the processing method, the semiconductor substrate 12 may be subjected to a thermal treatment (i.e., annealing process), which subjects the implanted layer 14 (FIG. 1) of semiconductor material to the thermal treatment. In an embodiment, the thermal treatment may be a rapid thermal anneal. In an embodiment, the rapid thermal anneal may heat the semiconductor substrate 12 to a peak temperature in a range of 900°C to 1125°C with a dwell time at the peak temperature of 30 milliseconds to 5 seconds.

The thermal treatment recrystallizes the more-lightly damaged semiconductor material of the implanted layer 14 adjacent to the top surface 11 into a layer 20 that includes single-crystal semiconductor material, such as single-crystal silicon. The layer 20 may have a thickness T1. The thermal treatment may also convert all or a portion of the more-heavily damaged semiconductor material of the implanted layer 14 into a damage layer 18. In an embodiment, the damage layer 18 may contain highly disordered semiconductor material that is non-single crystal and that lacks the crystal lattice structure of the overlying layer 20 and the underlying portion of the semiconductor substrate 12. In an embodiment, the damage layer 18 may contain grains of polycrystalline semiconductor material, such as polycrystalline silicon, and defects as residual damage in addition to the polycrystalline grains. In contrast to the damage layer 18, the recrystallized single-crystal semiconductor material in the layer 20 includes negligible disorder.

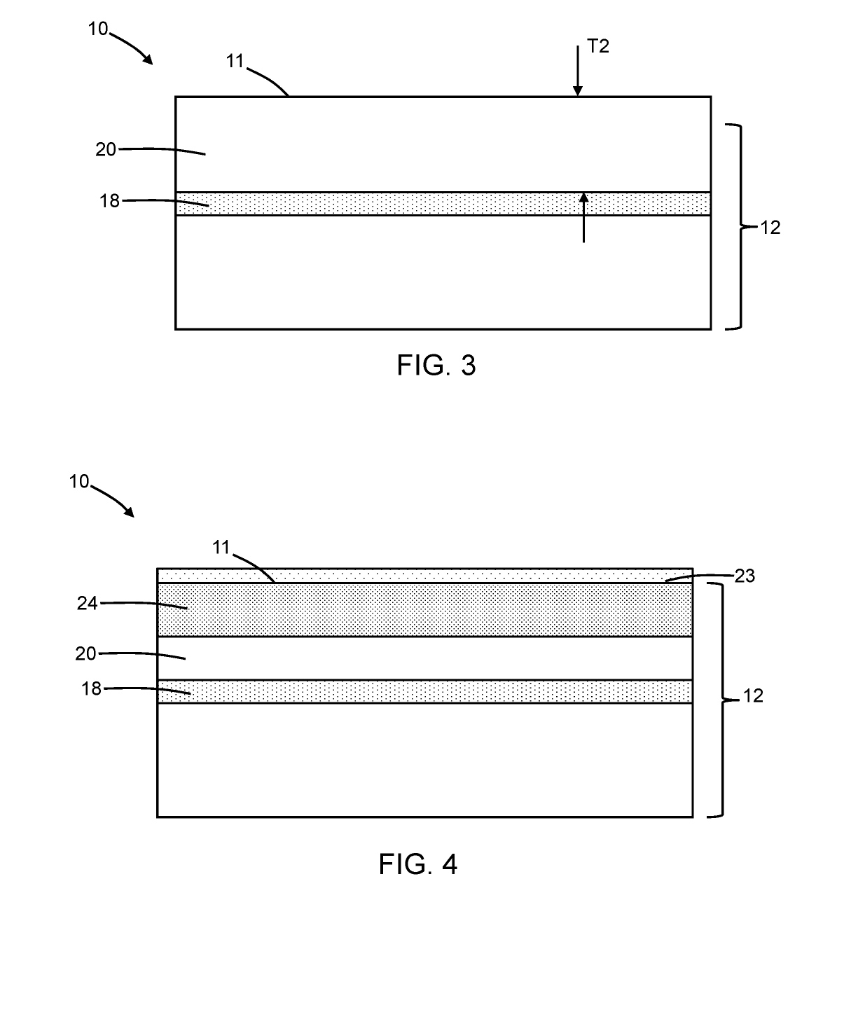

With reference to FIG. 3 in which like reference numerals refer to like features in FIG. 2 and at a subsequent fabrication stage of the processing method, the dielectric layer 13 may be removed after forming the damage layer 18 and the layer 20, and the layer 20 may be thickened through the formation of additional single-crystal semiconductor material. In an embodiment, the semiconductor material added to the layer 20 may be comprised of single-crystal silicon. The semiconductor material added to the layer 20 may be formed by an epitaxial growth and may be oriented with a <111> surface normal. The layer 20 has a final thickness T2, after the addition of the epitaxially-grown single-crystal semiconductor material, that is greater than the initial thickness T1 of recrystallized single-crystal semiconductor material alone. The single-crystal semiconductor material of the layer 20 may be characterized by a continuous, unbroken crystal lattice structure that extends throughout the layer 20, that has a noninterrupted repetition of the unit cell of the crystal lattice structure in three dimensions, and that lacks grain boundaries.

The top surface 11 of the semiconductor substrate 12 is relocated after the additions of the damage layer 18 of non-single-crystal semiconductor material and the layer 20 of single-crystal semiconductor material. The damage layer 20 is positioned in a vertical direction between the top surface 11 and the damage layer 18.

With reference to FIG. 4 in which like reference numerals refer to like features in FIG. 3 and at a subsequent fabrication stage of the processing method, a dielectric layer 23 comprised of, for example, an oxide of silicon, such as silicon dioxide, may be applied to the layer 20. An implanted layer 24 comprised of damaged or amorphous semiconductor material may be formed within the thickness of the layer 20. The implanted layer 24 may be similar or identical to the implanted layer 14 (FIG. 1). The implanted layer 24 is separated from the damage layer 18 by an underlying portion of the layer 20 that is undamaged by the ion implantation process forming the implanted layer 24.

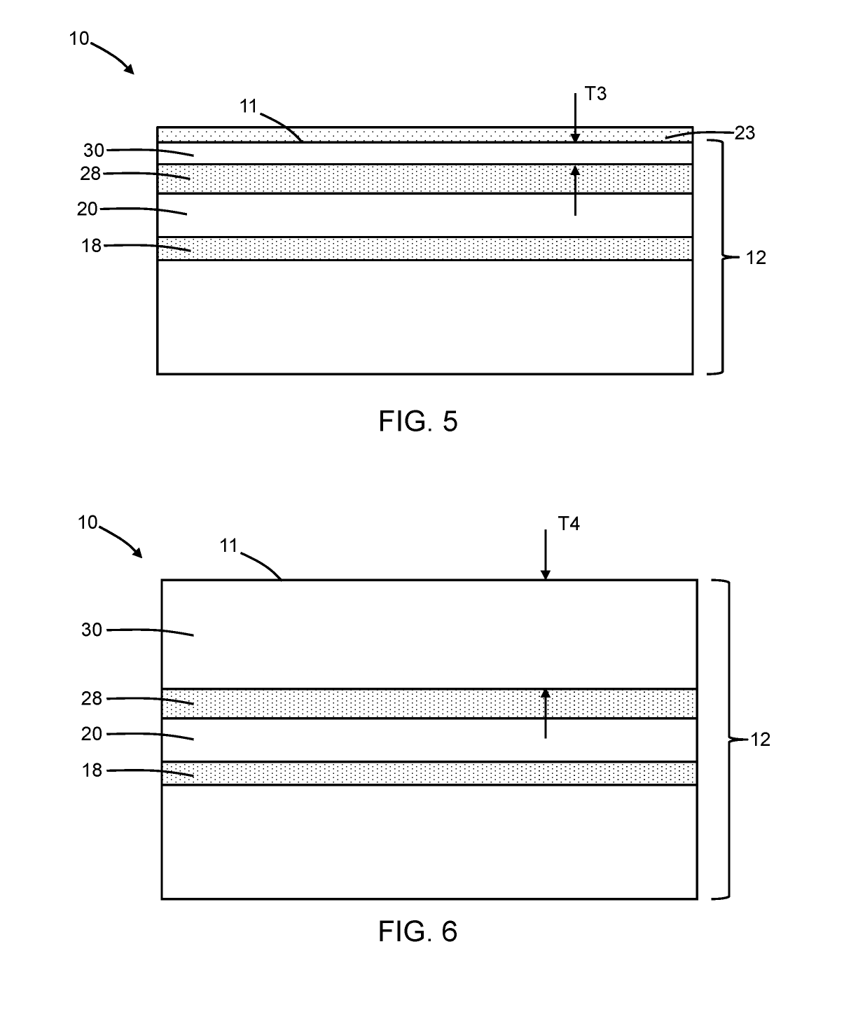

With reference to FIG. 5 in which like reference numerals refer to like features in FIG. 4 and at a subsequent fabrication stage of the processing method, the semiconductor substrate 12 is subjected to a thermal treatment, which subjects the implanted layer 24 (FIG. 4) of semiconductor material to the thermal treatment. Similar to the thermal treatment of the implanted layer 14, the thermal treatment recrystallizes the more-lightly damaged semiconductor material of the implanted layer 24 adjacent to the top surface 11 into a layer 30 that includes single-crystal semiconductor material, such as single-crystal silicon. The layer 30, which is similar or identical to the layer 20, may have a thickness T3. The thermal treatment may also convert all or a portion of the more-heavily damaged semiconductor material of the implanted layer 24 into a damage layer 28 that is similar or identical to the damage layer 18. In an embodiment, the damage layer 28 may have a thickness that is greater than the thickness of the damage layer 18. The larger thickness of the damage layer 28 may arise from tailoring the implantation conditions for the implanted layer 24 to produce a wider depth profile than the depth profile of the implanted layer 14 (FIG. 1). In contrast to the high level of disorder of the non-single-crystal semiconductor material contained in the damage layer 28, the recrystallized single-crystal semiconductor material in the layer 30 includes negligible disorder.

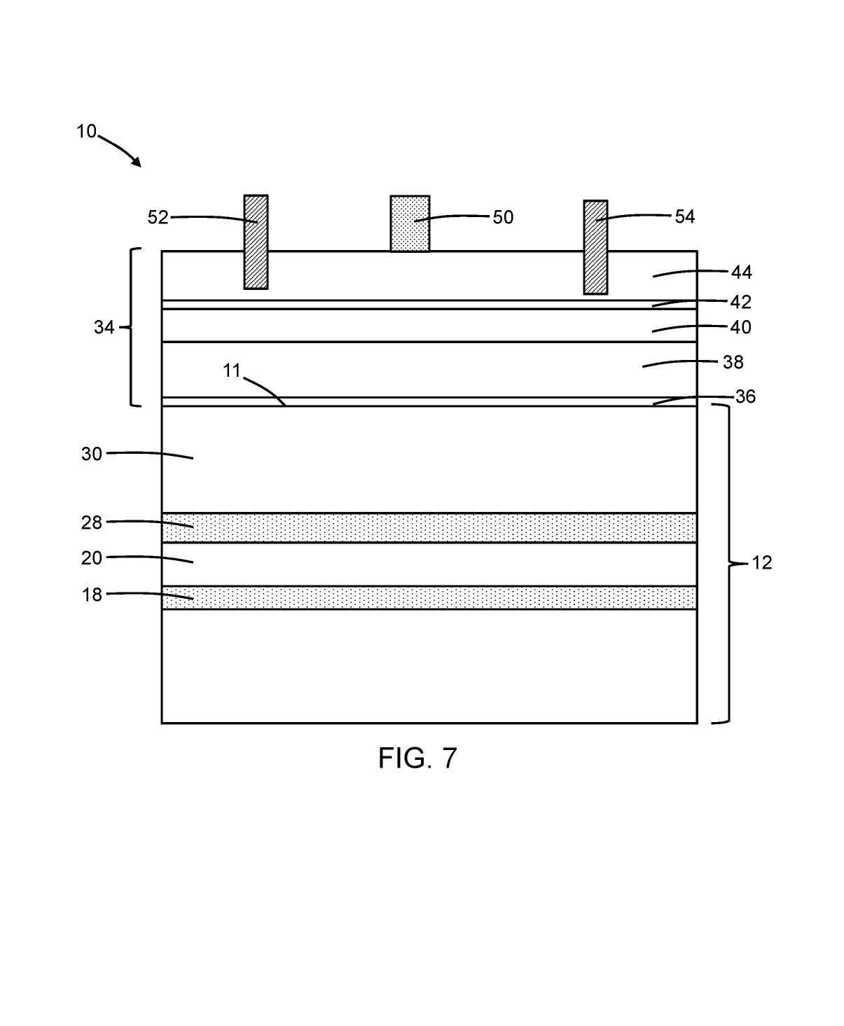

With reference to FIG. 6 in which like reference numerals refer to like features in FIG. 5 and at a subsequent fabrication stage of the processing method, the dielectric layer 23 may be removed after forming the damage layer 28 and the layer 30, and the layer 30 may be thickened through the formation of additional single-crystal semiconductor material. In an embodiment, the semiconductor material added to the layer 30 may be comprised of single-crystal silicon. The semiconductor material added to the layer 30 may be formed by an epitaxial growth and may be oriented with a <111> surface normal. The layer 30 has a final thickness T4, after the addition of the epitaxially-grown single-crystal semiconductor material, that is greater than the initial thickness T3 of recrystallized single-crystal semiconductor material alone. The single-crystal layers 20, 30 alternate with the damage layers 18, 28 in a vertical direction. The single-crystal layers 20, 30 and the damage layers 18, 28 are considered to be portions of the semiconductor substrate 12.

In an alternative embodiment, the layer 30 may be doped with a dopant that can be added by ion implantation with one or more implantation conditions or, alternatively, during epitaxial. In an embodiment, the layer 30 may be doped with a concentration of a dopant that has a smaller atomic size than the atoms of the semiconductor material of the layer 30. For example, the layer 30 may be doped with boron having atoms that are approximately twenty-five percent (25%) smaller than silicon atoms. In an embodiment, the layer 30 may be heavily doped with the dopant. In an embodiment, the layer 30 may be doped with boron at a concentration greater than or equal to 2.25x10²⁰ atoms/cm⁻³. The ions may be generated from a suitable source gas and implanted into the semiconductor substrate 12 with one or more implantation conditions using an ion implantation tool. The implantation conditions, such as ion species, dose, and energy, for the ion implantation process may be selected to tune the characteristics of the implantation.

The top surface 11 of the semiconductor substrate 12 is relocated after the additions of the damage layer 18 of non-single-crystal semiconductor material, the layer 20 of single-crystal semiconductor material, the damage layer 28 of non-single-crystal semiconductor material, and the layer 30 of single-crystal semiconductor material. The damage layer 28 and the layer 30 are positioned in a vertical direction between the top surface 11 and the damage layer 18. The damage layer 28 and the layer 30 are also positioned in a vertical direction between the top surface 11 and the layer 20.

With reference to FIG. 7 in which like reference numerals refer to like features in FIG. 6 and at a subsequent fabrication stage of the processing method, a layer stack 34 may be formed on the layer 30 and, therefore, on the top surface 11 of the semiconductor substrate 12. The layer stack 34 may include a seed layer 36, a buffer layer 38, a channel layer 40, a spacer layer 42, and a barrier layer 44 each containing one or more compound semiconductor materials. The layers 36, 38, 40, 42, 44 may be serially deposited using an epitaxial growth process to form the layer stack 34. The layer stack 34 may have a thickness, for example, on the order of five (5) micrometers.

Each of the layers 36, 38, 40, 42, 44 of the layer stack 34 may have a crystal structure that is single crystal or, alternatively, a crystal structure that is substantially single crystal with varying levels of crystalline defectivity present. The seed layer 36, which provides a thin nucleation layer for the growth of the buffer layer 38, may be comprised of, for example, aluminum nitride. The buffer layer 38 may be comprised of one or more binary or ternary III-V compound semiconductor materials, such as aluminum gallium nitride, gallium nitride, aluminum nitride, or a layered combination of these materials. The buffer layer 38 is tailored in terms of material composition, doping, layering, and/or layer thickness to accommodate lattice mismatch, thermal property differences, and mechanical property differences between the material of the semiconductor substrate 12 and the material of the channel layer 40. The channel layer 40, which is positioned between the buffer layer 38 and the spacer layer 42, may be comprised of a binary III-V compound semiconductor material, such as gallium nitride. The channel layer 40 may include a sublayer comprised of undoped gallium nitride adjacent to the spacer layer 42 and a sublayer comprised of doped gallium nitride adjacent to the buffer layer 38. The spacer layer 42, which is positioned between the channel layer 40 and the barrier layer 44, may be comprised of a binary III-V compound semiconductor material, such as aluminum nitride, and the material of the spacer layer 42 may be characterized by a higher electrical resistivity than the material of the channel layer 40 or the material of the barrier layer 44. The barrier layer 44, which is positioned on the spacer layer 42, may contain a ternary III-V compound semiconductor, such as aluminum gallium nitride. A two-dimensional electron gas may be formed in the channel layer 40 near the interface with the spacer layer 42.

A gate electrode 50, a source ohmic contact 52, and a drain ohmic contact 54 of a high-electron-mobility transistor may be formed using the layer stack 34. The gate electrode 50 may be positioned in a lateral direction between source ohmic contact 52 and the drain ohmic contact 54. In an embodiment, the gate electrode 50 may be comprised of nickel, titanium, or a combination of metals such as a combination of nickel and aluminum. The source ohmic contact 52 and the drain ohmic contact 54 may comprised of a combination of metals, such as a combination of aluminum, titanium, and silicon. The gate electrode 50 may be biased to control electron flow within the two-dimensional electron gas between the source ohmic contact 52 and the drain ohmic contact 54.

The layer stack 34 and the semiconductor substrate 12 have a lattice mismatch represented by a difference in lattice parameters, such as lattice constant, between the materials of the layer stack 34 and the material of the semiconductor substrate 12. The lattice mismatch induces stress in the crystal structure of the materials of the layer stack 34, which if unrelieved can lead to defects, such as cracks or dislocations, that can propagate from the top surface 11 upwardly through the layer stack 34. The damage layer 18 and the damage layer 28, in combination with the layer 20 and the layer 30, assist the buffer layer 38 with reducing the stress and defect propagation. The damage layer 18 and the damage layer 28, in combination with the layer 20 and the layer 30, function as a stress relief region inside the semiconductor substrate 12. The alternating single-crystal and non-single crystal layers may relieve strain in the layer stack 34 and may transfer strain to the region of the semiconductor substrate 12 beneath the damage layer 18. The strain relief may reduce the risk of breakage during processing and may permit the thickness of the layer stack 34 to be reduced.

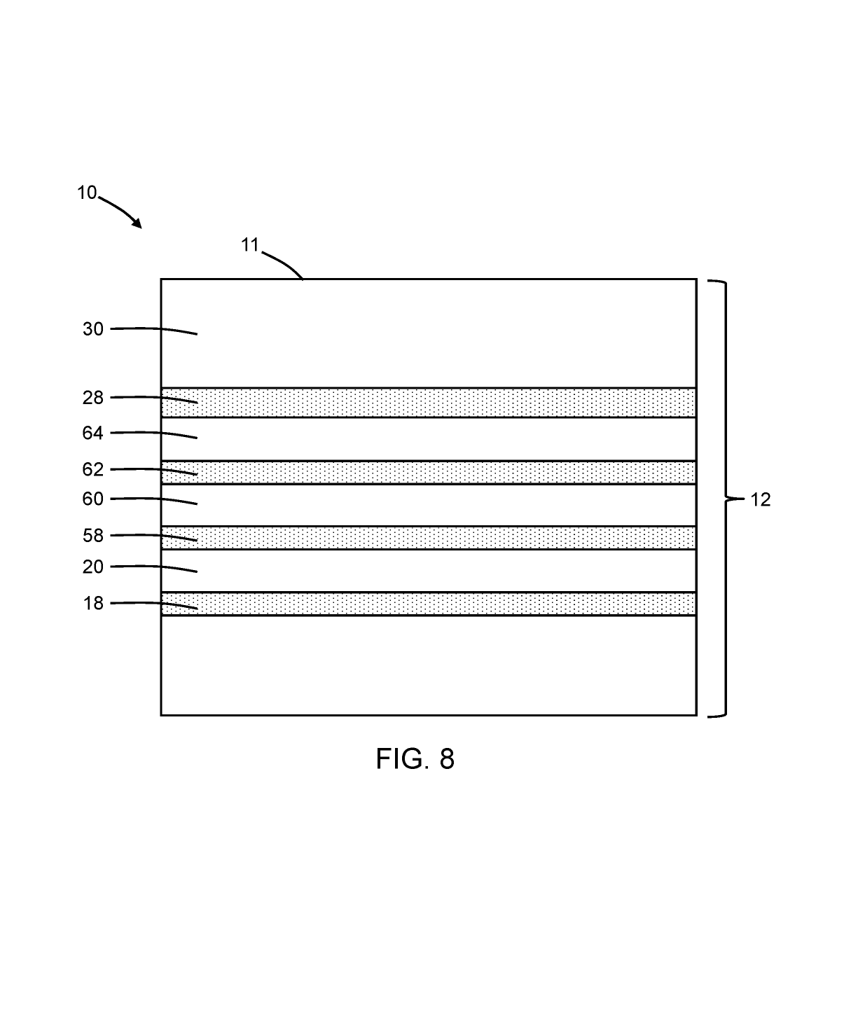

With reference to FIG. 8 and in accordance with alternative embodiments, a damage layer 58, a layer 60, a damage layer 62, and a layer 64 may be added to the semiconductor substrate 12 as additional alternating single-crystal and non-single crystal layers. The damage layer 58 and the layer 60 may be formed in the same manner as the damage layer 28 and the layer 30. The damage layer 62 and the layer 64 may also be formed in the same manner as the damage layer 28 and the layer 30.

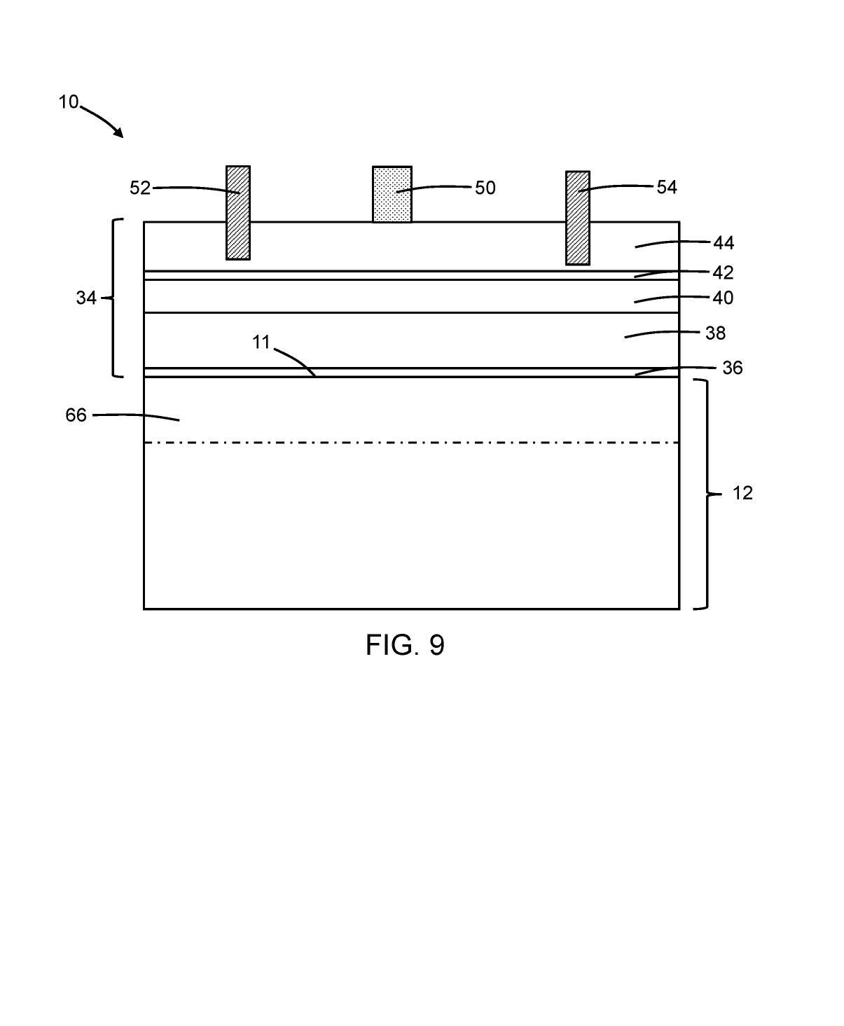

With reference to FIG. 9 and in accordance with alternative embodiments, an implanted layer 66 may be formed in the semiconductor substrate 12 by ion implantation. The implanted layer 66 is positioned adjacent to the top surface 11 of the semiconductor substrate 12. The ions may be generated from a suitable source gas and implanted into the semiconductor substrate 12 with one or more implantation conditions using an ion implantation tool. The implantation conditions, such as ion species, dose, and energy, for the ion implantation process may be selected to tune the characteristics of the implanted layer 66.

In an embodiment, the implanted layer 66 may be doped with a concentration of a dopant that has a smaller atomic size than the atoms of the semiconductor material of the implanted layer 66. For example, the implanted layer 66 may be doped with boron having atoms that are approximately twenty-five percent (25%) smaller than silicon atoms. In an embodiment, the implanted layer 66 may be heavily doped with the dopant. In an embodiment, the implanted layer 66 may be doped with boron at a concentration greater than or equal to 2.25x10²⁰ atoms/cm⁻³. In an embodiment, the implanted layer 66 may have a thickness of greater than or equal to three (3) micrometers to enable the effective distribution of the lattice strain.

The layer stack 34 may be formed directly on the top surface 11 of the semiconductor substrate 12 and immediately adjacent to the implanted layer 66 without forming the damage layers 18, 28 and the layers 20, 30. The implanted layer 66 may operate as a stress relief region within the semiconductor substrate 12. More specifically, the atoms introduced by implantation, which have a smaller atomic size than the atoms of the semiconductor material of the semiconductor substrate 12, cause the lattice constant of the semiconductor material of the semiconductor substrate 12 to be closer to the lattice constant of the semiconductor materials of the layer stack 34.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. Different features may “overlap” if a feature extends over, and covers a part of, another feature. A feature may “overlie” another feature if a feature is positioned over another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor substrate including a top surface, a first layer, and a second layer, the first layer between the second layer and the top surface, the semiconductor substrate comprising a semiconductor material; and
a layer stack on the top surface of the semiconductor substrate,
wherein the semiconductor material of the first layer is single crystal, and the semiconductor material of the second layer is non-single-crystal.

2. The structure of claim 1 wherein the semiconductor substrate includes a third layer and a fourth layer, the third layer is arranged between the fourth layer and the top surface, the semiconductor material of the third layer is single crystal, and the semiconductor material of the fourth layer is non-single-crystal.

3. The structure of claim 2 wherein the semiconductor material is silicon.

4. The structure of claim 1 wherein the semiconductor material of the first layer is oriented with a <111> surface normal.

5. The structure of claim 1 further comprising:
a gate electrode on the layer stack.

6. The structure of claim 1 wherein the first layer includes a concentration of a dopant with atoms having a smaller atomic size than atoms of the semiconductor material of the first layer.

7. The structure of claim 6 wherein the dopant is boron, and the semiconductor material is silicon.

8. The structure of claim 7 wherein the concentration is greater than or equal to 2.25x10²⁰ atoms/cm⁻³.

9. The structure of claim 1 wherein the layer stack includes a plurality of III-V compound semiconductor layers.

10. The structure of claim 9 further comprising:
a high-electron-mobility transistor including a gate electrode on the layer stack.

11. A structure comprising:
a semiconductor substrate comprising a single-crystal semiconductor material, the semiconductor substrate including a top surface and a layer adjacent to the top surface, and the layer comprising a concentration of a dopant with atoms having a smaller atomic size than atoms of the single-crystal semiconductor material; and
a layer stack on the top surface of the semiconductor substrate.

12. The structure of claim 11 wherein the layer has a thickness of greater than or equal to three micrometers.

13. The structure of claim 11 wherein the dopant is boron, and the single-crystal semiconductor material is single-crystal silicon.

14. The structure of claim 13 wherein the concentration is greater than or equal to 2.25x10²⁰ atoms/cm⁻³.

15. The structure of claim 11 wherein the layer stack includes a plurality of III-V compound semiconductor layers.

16. The structure of claim 15 further comprising:
a high-electron-mobility transistor including a gate electrode on the layer stack.

17. A method comprising:
forming a first layer and a second layer of a semiconductor substrate, wherein the first layer is arranged between the second layer and a top surface of the semiconductor substrate, the semiconductor substrate comprises a semiconductor material, the semiconductor material of the first layer is single crystal, and the semiconductor material of the second layer is non-single-crystal; and
forming a layer stack on the top surface of the semiconductor substrate.

18. The method of claim 17 wherein forming the first layer and the second layer of the semiconductor substrate comprises:
forming a first implanted layer in the semiconductor substrate;
annealing the semiconductor substrate to convert the first implanted layer into the first layer and the second layer; and
epitaxially growing an additional thickness of the semiconductor material on the first layer.

19. The method of claim 18 further comprising:
forming a second implanted layer in the first layer;
annealing the semiconductor substrate to convert the second implanted layer into a third layer and a fourth layer, wherein the third layer is arranged between the fourth layer and the top surface, the semiconductor material of the third layer is single crystal, and the semiconductor material of the fourth layer is non-single-crystal; and
epitaxially growing an additional thickness of the semiconductor material on the third layer.

20. The method of claim 19 wherein the third layer includes a concentration of a dopant with atoms having a smaller atomic size than atoms of the semiconductor material of the third layer.
